(19) United States
(12) Patent Application Publication
(10) Pub. No.: US 2008/0149166 A1
(43) Pub. Date: Jun. 26, 2008

(54) Compact light conversion device and light source with high thermal conductivity wavelength conversion material

(75) Inventors: Karl W. Beeson, Princeton, NJ (US); Scott M. Zimmerman, Baskin Ridge, NJ (US); Richard L. Ross, Del Mar, CA (US); William R. Livesay, San Diego, CA (US)

Correspondence Address: William Propp, Esq.;Goldeneye, Inc., Suite 233, 9747 Businesspark Avenue, San Diego, CA, 92131, US

(73) Assignee: Goldeneye, Inc.

(21) Appl. No.: 11/644,678

(22) Filed: Dec. 21, 2006

(51) Int. Cl. H01L 31/042

(52) U.S. Cl. 136/248

(57) ABSTRACT

A light conversion device and high-intensity, solid-state light source utilize wavelength conversion elements with a thermal conductivity greater than 1 watt per meter per degree Kelvin (W/m-K). Exemplary materials that have high thermal conductivity include monocrystalline solids, polycrystalline solids, substantially densified ceramic solids, amorphous solids or composite solids. The light conversion device and high-intensity, solid-state light source have at least one heat sink that is in direct thermal contact with the wavelength conversion element. The heat sink quickly dissipates heat generated within the wavelength conversion element in order to prevent the wavelength conversion element from overheating and undergoing thermal quenching of the wavelength conversion and light emission.

### TECHNICAL FIELD

The present invention is a light conversion device and light source that can be implemented using solid-state, light-emitting devices such as light emitting diodes (LEDs). The invention has a high thermal conductivity wavelength conversion material and also includes means for thermal cooling of such devices and light sources.

### BACKGROUND OF THE INVENTION

Solid-state lighting has expanded rapidly based on the development of efficient inorganic and organic light emitting diode devices. These LED devices tend to be narrow band optical emitters that must be combined or coupled with wavelength conversion materials to create useful white light sources. In particular, wavelength conversion means such as powder phosphors are used to broaden or shift the emission bands of blue or ultraviolet (UV) LEDs. Powder based phosphors are typically created using solid-state processes. The phosphors are then combined with various binders such as organic materials or inorganic glasses before being deposited directly onto the light emitting diode device. The phosphors are combined within the binder. They are held in suspension or embedded in a uniform density within the binder. Considerable powdered-phosphor prior art exists that discloses various means to create uniform thickness coatings, methods to increase efficiency and a host of improved wavelength conversion and binder materials.

The conversion of an excitation wavelength into an emitted wavelength by a wavelength converting material is not 100 percent efficient. The converted light has a longer wavelength and has lower photon energy than the excitation light. The shift in wavelength is known as the Stokes shift. The difference in energy between the excitation photon energy and the emission photon energy is converted into heat energy. For powdered phosphors, this can lead to a significant amount of local heating within the wavelength conversion material following exposure to the excitation light. The heating is due to the lack of an adequate thermal conduction path from the phosphor powder grains to the ambient environment and can result in thermal quenching of the wavelength conversion and light emission and a subsequent reduction in the emitted light flux. The thermal conductivity of a phosphor powder in a binder is typically less than 1 watt per meter per degree Kelvin (W/m-K).

As an example of undesirable thermal effects in powdered phosphors, the light output of cerium-doped yttrium aluminum garnet (Ce:YAG) powder starts to decrease at temperatures exceeding 150 C. Other wavelength converting materials have even lower thermal quenching temperatures. In the case of low-powered devices such as backlights used in cell phones, the thermal quenching temperature is never exceeded. However, as solid-state lighting moves into high-powered applications such as directional lighting for projection displays or spot illumination and non-directional high-powered applications such as liquid crystal display television (LCD TV) backlighting, the temperature of the wavelength converting material will increase significantly. While the thermal quenching characteristics can be improved using alternate materials, some tradeoffs regarding light output efficiency or spectral content of the converted light are usually required. Although such approaches are adequate for low levels of LED excitation, the lack of an adequate thermal conduction path to ambient limits the maximum light flux level one can use to excite the powdered phosphors.

Another disadvantage of using a powdered phosphor with a binder is that the high surface area of the powdered phosphor results in a variety of degradation mechanisms for both the phosphor and the binder. For example, the binders that surround the phosphor particles, especially organic-based binders, tend to degrade and/or turn yellow under high light flux levels.

Alternately, the phosphor area or volume can be increased to reduce the thermal load per phosphor particle as seen in phosphor-at-a-distance approaches. However, the approach of increasing the phosphor area or volume makes optical coupling inefficient in applications requiring a small source size or small source etendue. In addition, increasing the phosphor area or volume also increases the overall size and weight of the LED source with a higher cost associated with the larger volume of the wavelength conversion material. This deficiency in the phosphor-at-a-distance approach is at least partly driven by the lack of an efficient thermal conduction path for the wavelength conversion material.

One example of the prior art for thermal management of LED light sources is illustrated in FIGS. 1A and 1B. FIG. 1A is a side cross-sectional view of a light source 100 that includes an LED 110, a wavelength conversion layer 120 and a heat sink 130. The wavelength conversion layer consists of phosphor particles 122 embedded in a binder 124. The LED 110 includes a top contact 118, a multilayer semiconductor structure 112, a bottom contact 114 and a sub-mount 116. The sub-mount is usually both a thermal conductor and an electrical conductor. Electrical connections to the LED are made to the top contact by wire 119 and by a connection (not shown) to the bottom contact or sub-mount. As illustrated schematically by arrow 140 in FIG. 1A and by FIG. 1B, heat flow from the wavelength conversion layer in light source 100 is a series pathway from the wavelength conversion layer through the LED to the heat sink. The heat flow can be characterized by a thermal resistance 160 (R_{WCL}) for the wavelength conversion layer, a thermal resistance 170 (R_{LED}) for the LED and a thermal resistance 180 (R_{HS}) for heat flow from the heat sink to the ambient environment. The units of thermal resistance are usually given in degrees Centigrade per watt of electrical power input to the device. In this case, the electrical power input for the wavelength conversion layer, the LED and the heat sink is the electrical power applied to the LED. Heat generated in the wavelength conversion layer must flow through the LED to get to the heat sink, thereby increasing the temperature of the LED and possibly lowering the light output of the LED. Likewise, heat from the LED can flow upward (not shown) and increase the temperature and lower the light output of the wavelength conversion layer. Both heat flows can be tolerated in low-power devices, but will significantly reduce the performance of high-power devices.

Another example of the prior art for the thermal management of wavelength converting materials in LED light sources is illustrated in FIGS. 2A and 2B. FIG. 2A is a side cross-sectional view of a light source 200 that includes an LED 110, a wavelength conversion layer 220 and a heat sink 230. The wavelength conversion layer consists of phosphor particles 222 embedded in a binder 224. LED 110 is described above in FIGS. 1A and 1B. Electrical connections to the LED are made to the top contact by wire 119 and by a connection (not shown) to the bottom contact, sub-mount or heat sink. In this light source, heat flow from the wavelength conversion layer to the heat sink can follow two pathways. The first thermal path is illustrated schematically by thermal pathway 242 in FIG. 2A and FIG. 2B. The second thermal path is illustrated schematically by pathway 244 in FIG. 2A and FIG. 2B. Considering the first thermal path 242, heat can flow directly from the wavelength conversion layer 220 to the heat sink 230 and from the heat sink to ambient. The heat in thermal path 242 does not go through the LED. The heat flow in the first path can be characterized by a thermal resistance 260 (R_{WCL}) for the wavelength conversion layer and a thermal resistance 280 (R_{HS}) for heat flow from the heat sink to the ambient environment. Alternatively, heat can flow along the second thermal path 244 from the wavelength conversion layer and through the LED to the heat sink. The heat flow in the second path can be characterized by a thermal resistance 260 (R_{WCL}) for the wavelength conversion layer, a thermal resistance 270 (R_{LED}) for the LED and a thermal resistance 280 (R_{HS}) for heat flow from the heat sink to the ambient environment. In this example of the prior art, some of the heat generated by the wavelength conversion layer can flow directly to the heat sink without flowing through the LED. However, some of the heat generated in the wavelength conversion layer will still flow through the LED to get to the heat sink, thereby increasing the temperature and possibly lowering the light output of the LED. Likewise, heat from the LED can flow upward (not shown) and increase the temperature and lower the light output of the wavelength conversion layer. Both heat flows can be tolerated in low-power devices, but can significantly reduce the performance of high-power devices. In addition, all the heat must still go through a single heat sink, which may not be able to handle the heat load for both the LED and the wavelength conversion layer in high-power devices. Finally, the wavelength conversion layer for powder-in-a-binder approaches has low thermal conductivity and high thermal resistance.

Mueller et al. in U.S. Patent Application Publication 20050269582 disclose a luminescent ceramic and an LED that are both in thermal contact with a single sub-mount. The sub-mount serves as a single heat sink for the light source. There are two thermal pathways from the luminescent ceramic to the sub-mount, one through the LED and another directly to the sub-mount. The two pathways in the Mueller device are operationally equivalent to the two thermal pathways shown in FIG. 2B. However, Mueller et al. do not disclose the use of a thermally conducting monocrystalline wavelength conversion element or other non-ceramic element in direct thermal contact with a heat sink and do not disclose the use of two or more separate heat sinks for the luminescent ceramic and the LED. Furthermore, Mueller et al. do not disclose physically separating the luminescent ceramic and the LED to prevent direct thermal contact between the two elements. Having direct thermal contact between the LED and the luminescent ceramic and having only one heat sink for both elements may cause the luminescent ceramic to overheat the LED or cause the LED to overheat the luminescent ceramic in the Mueller et al. LED. Either type of overheating can result in a reduction in light output from the LED.

Beeson and Zimmerman, who are also inventors for the present patent application, have disclosed a light-recycling, cavity-based approach to enhancing the output of wavelength conversion materials in U.S. patent application Ser. No. 11/430,277, which was published as U.S. Patent Application Publication No. 20060203468 and which is herein incorporated by reference in its entirety. In the cavity-based approach, the wavelength conversion material may be a powdered phosphor material or may be a solid phosphor layer. The solid phosphor layer may be a doped single-crystal solid, a doped polycrystalline solid or a doped amorphous solid. Also disclosed is a heat sink attached to one surface of the wavelength conversion layer. The purpose of the heat sink is to remove heat that can build up in the wavelength conversion layer when light from LEDs is absorbed by the layer.

There is a need for compact, high-power light conversion devices that can convert light from one wavelength range to a second wavelength range and that include improved thermal conductivity means to prevent overheating. There is also a need for a high-power light conversion device that includes an integrated electrical connection in order to simplify connections to light-emitting devices such as LEDs. In addition, there is a need for very compact, high-intensity, LED-based light sources that include wavelength conversion materials without the effects of thermal overload and thermal quenching of the wavelength conversion and light emission.

### SUMMARY OF THE INVENTION

Compact, high-intensity, light conversion devices and compact, high-intensity, solid-state light sources utilize wavelength conversion elements that convert light of a first wavelength range into light of a second wavelength range and preferably have a thermal conductivity greater than 1 watt per meter per degree Kelvin (W/m-K). More preferred wavelength conversion elements have a thermal conductivity greater than 10 W/m-K. Most preferred wavelength conversion elements have a thermal conductivity greater than 50 W/m-K.

Exemplary materials that have high thermal conductivity and that can be used for the wavelength conversion devices and light sources of this invention are monocrystalline solids, polycrystalline solids, substantially densified ceramic solids such that sufficient thermal conductivity is present to enable the invention, amorphous solids and composite solids exhibiting sufficient thermal conductivity to enable the invention. Examples chemical compounds include, but are not limited to, suitably doped oxides, nitrides, oxynitrides, silicates, halosilicates, phosphates, halophosphates, borates, aluminates, gallates, garnets, molybdates, tungstates, halides, oxyhalides, sulfates, oxysulfides, and sulfides.

Embodiments of this invention include at least one heat sink that is in direct thermal contact with the wavelength conversion element. Heat generated within the wavelength conversion element is dissipated quickly to the ambient environment in order to prevent the wavelength conversion element from overheating and undergoing thermal quenching of the wavelength conversion and light emission.

One embodiment of this invention is a wavelength conversion device that includes a wavelength conversion element that has an input surface and an output surface, a heat sink in thermal contact with the wavelength conversion element and an optional thermally conducting reflector interposed between the wavelength conversion element and the heat sink. The wavelength conversion element converts light of a first wavelength range into light of a second wavelength range. The second wavelength range is different than the first wavelength range. The wavelength conversion device may include additional elements such as a first dichroic mirror fabricated on or positioned near the output surface, a second dichroic mirror fabricated on or positioned near the input surface, light extraction elements fabricated on the output surface or an electrical connection fabricated on or embedded in the input surface. The electrical connection facilitates the formation of an electrical interconnection to a light-emitting device that is positioned adjacent to the input surface of the wavelength conversion device.

Another embodiment of this invention is a light source that includes a wavelength conversion element that has an input surface and an output surface, an LED positioned adjacent to the input surface and a heat sink in thermal contact with both the wavelength conversion element and the LED. The LED may or may not be in direct thermal contact with the wavelength conversion element. Preferably the LED and wavelength conversion element are not in direct thermal contact so that the wavelength conversion element will not overheat the LED and the LED will not overheat the wavelength conversion element. If the wavelength conversion element is overheated, thermal quenching may occur and the light output from the wavelength conversion element will be reduced. If the LED is overheated, the LED will become less efficient and the light output from the LED will drop. The wavelength conversion element can optionally include an electrical connection fabricated on or embedded in the input surface of the element. The electrical connection on the wavelength conversion device facilitates the formation of an electrical interconnection to the adjacent LED.

Other embodiments of this invention include two or more heat sinks to cool the device or light source. For example, one embodiment of this invention is a light source that includes a wavelength conversion element that has an input surface and an output surface, a first heat sink that is in thermal contact with the wavelength conversion element, an LED positioned adjacent to the input surface and a second heat sink in thermal contact with the LED. The first heat sink is not in direct thermal contact with the second heat sink. The LED may or may not be in direct thermal contact with the wavelength conversion element. Preferably the LED and wavelength conversion element are not in direct thermal contact so that the wavelength conversion element will not overheat the LED and the LED will not overheat the wavelength conversion element. The wavelength conversion element can optionally include an electrical connection fabricated on or embedded in the input surface of the element. The electrical connection on the wavelength conversion device facilitates the formation of an electrical interconnection to the adjacent LED.

### BRIEF DESCRIPTION OF THE DRAWINGS

A more detailed understanding of the present invention, as well as other objects and advantages thereof not enumerated herein, will become apparent upon consideration of the following detailed description and accompanying drawings, wherein:

FIG. 1A is a side cross-sectional view of one example of the prior art. FIG. 1B schematically illustrates the thermal pathway for the example in FIG. 1A.

FIG. 1B is a side cross-sectional view of another example of the prior art. FIG. 1B schematically illustrates the two thermal pathways for the example in FIG. 2A.

FIG. 3 illustrates examples of materials that can be utilized to fabricate wavelength conversion elements.

FIGS. 4A-4C illustrate side cross-sectional views of wavelength conversion devices of this invention that include one heat sink. FIG. 4D is a bottom plan view of the wavelength conversion device illustrated in FIG. 4C. FIG. 4E schematically illustrates the thermal pathways for the examples in FIGS. 4A-4D.

FIGS. 5A and 5B illustrate side cross-sectional views of wavelength conversion devices of this invention that include two heat sinks.

FIG. 6A is a side cross-sectional view of a wavelength conversion device having a first dichroic mirror on the output surface. FIG. 6B is a side cross-sectional view of a wavelength conversion device having a second dichroic mirror on the input surface. FIG. 6C is a side cross-sectional view of a wavelength conversion device with light extraction elements on the output surface.

FIG. 7A is a bottom plan view of a wavelength conversion device that has an electrical connection on the bottom surface. FIG. 7B is a side cross-sectional view of the same wavelength conversion device along the plane illustrated in FIG. 7A.

FIG. 8A is a bottom plan view of another wavelength conversion device that has an electrical connection on the bottom surface. FIG. 8B is a side cross-sectional view of the same wavelength conversion device along the plane illustrated in FIG. 8A.

FIG. 9A is a side cross-sectional view of a light source of this invention that has one heat sink. FIG. 9B schematically illustrates the thermal pathway for the example in FIG. 9A.

FIG. 10A is a side cross-sectional view of another light source of this invention that has one heat sink.

FIG. 11A is a side cross-sectional view of a light source of this invention that has more than one heat sink. FIG. 11B schematically illustrates the thermal pathway for the example in FIG. 11A.

FIGS. 12A and 12C are side cross-sectional views of another light source of this invention that more than one heat sink. FIG. 12B schematically illustrates the thermal pathway for the example in FIG. 11A.

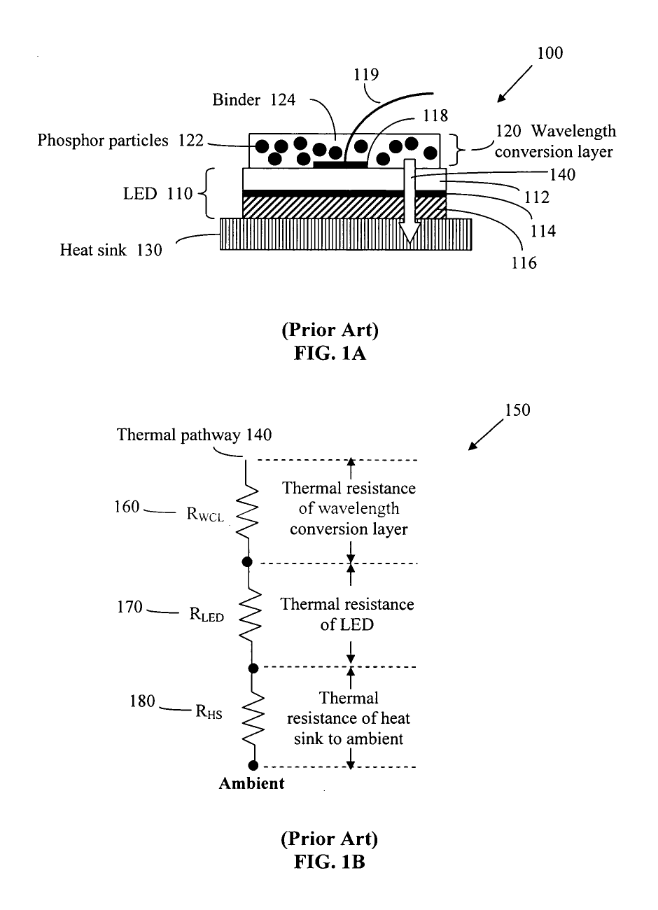

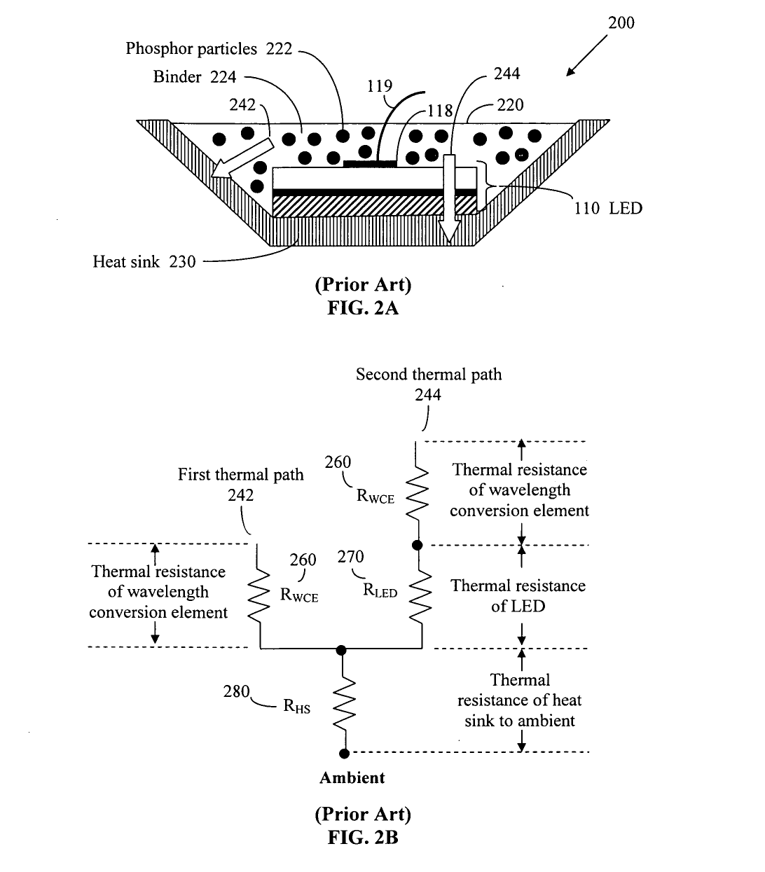

### DETAILED DESCRIPTION OF THE PREFERRED EMBODIMENTS

The preferred embodiments of the present invention will be better understood by those skilled in the art by reference to the above listed figures. The preferred embodiments of this invention illustrated in the figures are not intended to be exhaustive or to limit the invention to the precise form disclosed. The figures are chosen to describe or to best explain the principles of the invention and its applicable and practical use to thereby enable others skilled in the art to best utilize the invention.

Compact, high-intensity light conversion devices and compact, high-intensity, solid-state light sources utilize wavelength conversion materials that preferably have a thermal conductivity greater than 1 watt per meter per degree Kelvin (W/m-K). Exemplary wavelength conversion materials are monocrystalline solids, polycrystalline solids, substantially densified ceramic solids, amorphous solids or composite solids. Substantially densified ceramics are ceramics that have preferably been densified to at least 80 percent of bulk density and more preferably to at least 90 percent of bulk density. Densification can be accomplished by heating powdered starting materials at high temperature and optionally high pressure in order to achieve grain growth and consolidation. High densification removes void spaces to achieve higher thermal conductivity than the powdered starting materials.

The wavelength conversion materials include materials that exhibit phosphorescence and/or fluorescence. The wavelength conversion materials convert light of a first wavelength range into light of a second wavelength range, where the second wavelength range is different than the first wavelength range. The light of a first wavelength range can be in any part of the optical spectrum. Preferably the light of a first wavelength is in the blue or ultraviolet regions of the optical spectrum. The light of a second wavelength range normally has a longer wavelength and lower photon energy than the light of a first wavelength range allowing for visible and infrared light emission.

Examples of wavelength conversion materials that can be utilized for this invention include, but are not limited to, suitably doped oxides, nitrides, oxynitrides, silicates, halosilicates, phosphates, halophosphates, borates, aluminates, gallates, garnets, molybdates, tungstates, halides, oxyhalides, sulfates, oxysulfides, and sulfides. It is preferable that the monocrystalline, polycrystalline, substantially densified ceramic, amorphous or composite versions of these materials have thermal conductivity greater than 1 W/m-K. More preferred wavelength conversion materials have a thermal conductivity greater than 10 W/m-K. Most preferred wavelength conversion materials have a thermal conductivity greater than 50 W/m-K.

Suitable wavelength conversion materials for this invention are solid transparent or translucent host materials into which one or more luminescent dopant materials or quantum dot materials are dispersed. Typical dopants include, but are not limited to, ions of the lanthanide (rare earth) elements or, alternatively, ions such as manganese, magnesium, calcium, strontium, barium, bismuth, chromium, titanium, vanadium or cobalt. The lanthanide elements are lanthanum, cerium, praseodymium, neodymium, promethium, samarium, europium, gadolinium, terbium, dysprosium, holmium, erbium, thulium, ytterbium and lutetium. Optical host materials include, but are not limited to, sapphire (Al₂O₃), gallium arsenide (GaAs), beryllium aluminum oxide (BeAl₂O₄), zinc oxide (ZnO), magnesium fluoride (MgF₂), indium phosphide (InP), gallium phosphide (GaP), any garnet material such as yttrium aluminum garnet (YAG or Y₃Al₅O₁₂) or terbium-containing garnet, yttrium-aluminum-lanthanide oxide compounds, yttrium-aluminum-lanthanide-gallium oxide compounds, yttrium oxide (Y₂O₃), calcium or strontium or barium halophosphates (Ca,Sr,Ba)₅(PO₄)₃(Cl,F), the compound CeMgAl₁₁O₁₉, lanthanum phosphate (LaPO₄), lanthanide pentaborate materials ((lanthanide)(Mg,Zn)B₅O₁₀), the compound BaMgAl₁₀O₁₇, the compound SrGa₂S₄, the compounds (Sr,Mg,Ca,Ba)(Ga,Al,In)₂S₄, the compound SrS, the compound ZnS and nitridosilicate. There are several exemplary wavelength conversion materials that can be excited at 250 nanometers or thereabouts. An exemplary red emitting wavelength conversion material is Y₂O₃:Eu³⁺. An exemplary yellow emitting wavelength conversion material is YAG:Ce³⁺. Exemplary green emitting wavelength conversion materials include CeMgAl₁₁O₁₉:Tb³⁺, ((lanthanide)PO₄:Ce³⁺,Tb³⁺) and GdMgB₅O₁₀:Ce³⁺,Tb³⁺. Exemplary blue emitting wavelength conversion materials are BaMgA₁₀O₁₇:Eu and (Sr,Ba,Ca)₅(PO₄)₃Cl:Eu²⁺. For longer wavelength LED excitation in the 400 to 500 nanometer wavelength region or thereabouts, exemplary optical inorganic materials include yttrium aluminum garnet (YAG or Y₃Al₅O₁₂), terbium-containing garnet, yttrium oxide (Y₂O₃), YVO₄, SrGa₂S₄, (Sr,Mg,Ca,Ba)(Ga,Al,In)₂S₄, SrS, and nitridosilicate. Exemplary wavelength conversion materials for LED excitation in the 400 to 500 nanometer wavelength region include YAG:Ce³⁺, YAG:Ho³⁺, YAG:Pr³⁺, SrGa₂S₄:Eu²⁺, SrGa₂S₄:Ce³⁺, SrS:Eu²⁺ and nitridosilicates doped with Eu²⁺. Quantum dot materials are small particles of inorganic semiconductors having particle sizes less than about 40 nanometers. Exemplary quantum dot materials include, but are not limited to, small particles of CdS, CdSe, ZnSe, InAs, GaAs and GaN. Quantum dot materials can absorb light at one wavelength and then re-emit the light at different wavelengths that depend on the particle size, the particle surface properties, and the inorganic semiconductor material. Because of their small size, quantum dot materials dispersed in transparent host materials exhibit low optical backscattering.

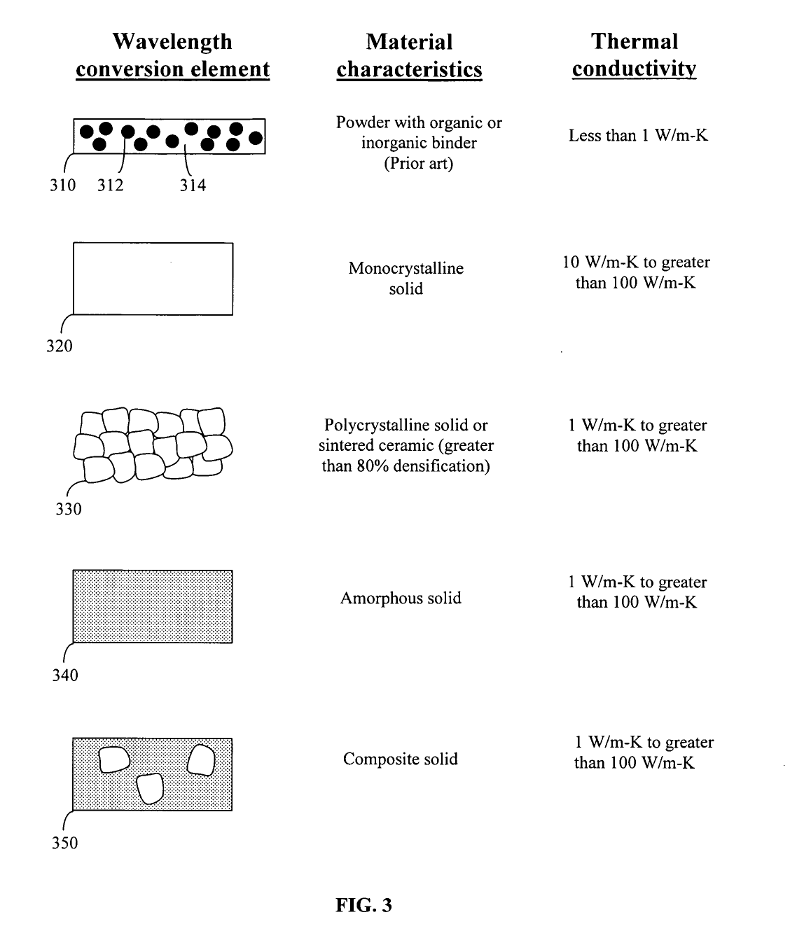

One example of a wavelength conversion material of the prior art is a powdered phosphor. Powdered phosphors are generally mixed with organic or inorganic binders. Wavelength conversion material 310 in FIG. 3 illustrates powdered phosphor grains 312 embedded in binder 314. Powdered phosphors embedded in binder materials usually have thermal conductivities less than 1 W/m-K and are therefore not suitable materials for this invention.

Examples of materials shown in FIG. 3 that do have thermal conductivities greater than 1 W/m-K and that are suitable for this invention include, but are not limited to, monocrystalline solids 320, polycrystalline solids 330, substantially densified ceramic solids 330, amorphous solids 340 or composite solids 350.

Composite solids are mixtures of two or more solids. For example, a composite solid may be a mixture of two or more ceramic materials, a mixture of two or more polycrystalline materials or a mixture of polycrystalline grains embedded in an amorphous solid as illustrated by composite solid 350 in FIG. 3.

Examples of thermally conducting monocrystalline solids 320 that have thermal conductivities greater than 10 W/m-K include, but are not limited to, garnet materials such as YAG and yttrium oxide materials (Y₂O₃). Examples of appropriate YAG materials are cerium-doped YAG (Ce:YAG) and neodymium-doped YAG (Nd:YAG). An example of an appropriate yttrium oxide material is europium-doped Y₂O₃ (Eu: Y₂O₃).

Examples of monocrystalline solids 320 that have thermal conductivities greater than 50 W/m-K include, but are not limited to, zinc oxide (ZnO) containing materials. Examples of appropriate ZnO materials include bismuth-doped ZnO (Bi:ZnO), zinc-doped ZnO (Zn:ZnO) and sulfur-doped ZnO (S:ZnO).

Examples of thermally conducting polycrystalline solids 330 that have thermal conductivities greater than 1 W/m-K include, but are not limited to, doped ZnO containing polycrystalline materials. Such materials can be produced, for example, by various chemical vapor deposition processes.

Examples of thermally conducting substantially densified ceramic solids 330 that have thermal conductivities greater than 1 W/m-K include sintered yttrium aluminum garnets (YAG) powdered materials and sintered zinc oxide powdered materials that are preferably densified to at least 80%. More preferably, such materials are densified to at least 90%. Powdered phosphors that normally have low thermal conductivity when mixed with organic or inorganic binders can have much higher thermal conductivities when sintered into solid ceramic elements. An example of an appropriate sintered YAG material is cerium-doped YAG (Ce:YAG) powder that is sintered and densified to at least 80%.

Amorphous solids 340 in general have lower thermal conductivities than single-crystalline and polycrystalline materials. Doped glasses such as neodymium-doped glasses have thermal conductivities in the range of 0.7-1.1 W/m-K. Pyrex glass has a thermal conductivity of approximately 1.1 W/m-K. An appropriate thermally conducting amorphous solid for this invention that has a thermal conductivity greater than 1 W/m-K is cerium-doped Pyrex glass.

Examples of thermally conducting composite solids 350 that have thermal conductivities greater than 1 W/m-K include mixtures of two or more polycrystalline, ceramic and amorphous materials. For example, embedding small grains of polycrystalline materials such as cerium-doped YAG or doped diamond powder into amorphous solids such as glass will increase the thermal conductivity of the resulting composite material relative to a pure amorphous solid.

Embodiments of this invention include at least one heat sink. In this specification, a heat sink is an element or assembly that carries away or radiates heat generated by a wavelength conversion element, a solid-state, light-emitting device or both. The heat sink is in thermal contact with the wavelength conversion element or both the wavelength conversion element and the solid-state, light-emitting device and transports heat to the ambient environment. The heat may be dissipated directly to the ambient environment by convective airflow or forced airflow. Alternatively, the heat from the heat sink may be dissipated to the ambient environment by additional elements or assemblies such as air fins, heat spreaders, heat pipes or liquid cooling assemblies. The heat sink is constructed from any material with high thermal conductivity, preferably greater than 50 W/m-K and more preferably greater than 200 W/m-K. Suitable materials include, but are not limited to, metals such a copper or aluminum, metal composites such as copper-tungsten or copper-molybdenum, ceramics such as aluminum nitride and silicon carbide and semiconductors such as silicon and diamond.

For high-intensity light sources that include wavelength conversion elements, it is very important to have a heat sink in direct thermal contact with the wavelength conversion element in order to prevent the element from overheating and undergoing thermal quenching. Thermal quenching can reduce the light output from the wavelength conversion element.

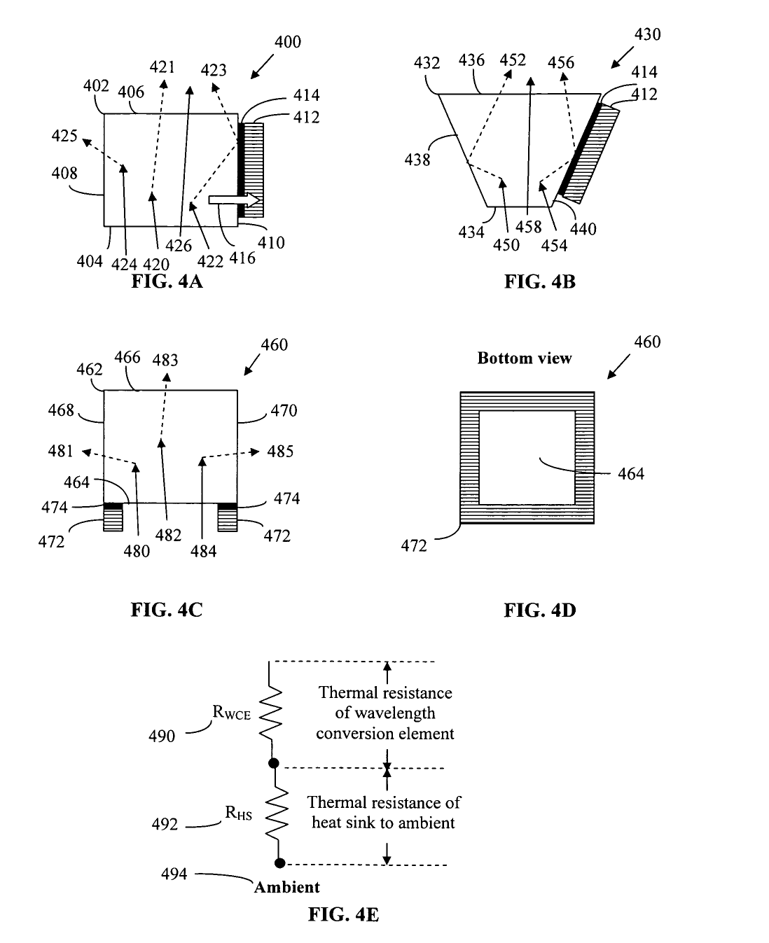

Example embodiments of this invention having a single heat sink are illustrated in FIG. 4.

One embodiment of the present invention is light conversion device 400 illustrated in a side cross-sectional view in FIG. 4A. Light conversion device 400 includes a wavelength conversion element 402, a heat sink 412 in thermal contact with the wavelength conversion element and an optional reflector 414.

The wavelength conversion element 402 is a three-dimensional solid fabricated from any wavelength conversion material that has a thermal conductivity greater than 1 W/m-K. In FIG. 4A, the wavelength conversion element 402 has a rectangular cross-section with four illustrated surfaces, 404, 406, 408 and 410, corresponding to four surfaces of a six-sided rectangular solid. In general, the three-dimensional solid may have any shape including geometrical shapes or more general shapes that enclose the volume of the wavelength conversion material. Example geometrical shapes include, but are not limited to, a cube, a rectangular solid, a trapezoidal-shaped solid, a cylinder, a tapered cylinder, a truncated pyramid or a solid with a polygonal cross-section. The surfaces of the solid may be planar or curved.

Suitable materials for wavelength conversion element 402 include monocrystalline solids, polycrystalline solids, substantially densified ceramic solids, amorphous solids and composite solids that have thermal conductivities greater than 1 W/m-K. Example materials are listed above.

The wavelength conversion element 402 has at least one light input surface and at least one light output surface. For the example device 400, surface 404 is a light input surface and at least surfaces 406 and 408 are light output surfaces. In addition, the front and back surfaces (not shown) of the wavelength conversion element may also be light output surfaces. Light of a first wavelength range enters the wavelength conversion element through the light input surface 404. The wavelength conversion element converts at least a portion of the light of a first wavelength range into light of a second wavelength range. The second wavelength range is different than the first wavelength range. The light of a second wavelength range is emitted isotropically within the wavelength conversion element. Therefore, the light of a second wavelength range may exit more than one surface of the wavelength conversion element. Some of the light of a second wavelength range will exit the designated light output surfaces 406 and 408. However, some of the light of a second wavelength range may also exit other surfaces including the light input surface 404, uncovered portions of surface 410, the front surface (not shown) and the back surface (not shown).

The heat sink 412 removes heat generated within the wavelength conversion element 402 during wavelength conversion. The heat sink is in thermal contact with surface 410 of the wavelength conversion element. Thermal contact means either direct physical contact or contact through another thermally conducting element, for example optional reflector 414, such that heat readily flows from the wavelength conversion element to the heat sink.

Optional reflector 414 is interposed between surface 410 of the wavelength conversion element 402 and the heat sink 412. Reflector 414 is useful for the light conversion device 400 if heat sink 412 has a low reflectivity to light. Preferably, the reflector reflects both light of a first wavelength and light of a second wavelength and prevents light from being absorbed by the heat sink. Preferably the reflectivity of reflector 414 is greater than 80%. More preferably the reflectivity is greater than 90%. Preferably the thermal conductivity of the reflector is greater than 50 W/m-K. Preferred reflective materials are aluminum and silver.

Light rays 420, 421, 423, 424, 424, 425 and 426 illustrate the operation of light conversion device 400. Light ray 420 of a first wavelength range enters wavelength conversion element 402 through surface 404. Wavelength conversion element 402 converts light ray 420 of a first wavelength range into light ray 421 of a second wavelength range. The second wavelength range is different than the first wavelength range. Light ray 421 of a second wavelength range exits wavelength conversion element 402 through surface 406.

Light ray 422 of a first wavelength range enters wavelength conversion element 402 through surface 404. Wavelength conversion element 402 converts light ray 422 of a first wavelength range into light ray 423 of a second wavelength range. The second wavelength range is different than the first wavelength range. Light ray 423 of a second wavelength range is reflected by reflector 414 on surface 410 and exits wavelength conversion element 402 through surface 406.

Light ray 424 of a first wavelength range enters wavelength conversion element 402 through surface 404. Wavelength conversion element 402 converts light ray 424 of a first wavelength range into light ray 425 of a second wavelength range. The second wavelength range is different than the first wavelength range. Light ray 425 of a second wavelength range exits wavelength conversion element 402 through surface 408.

Light ray 426 of a first wavelength range enters wavelength conversion element 402 through surface 404. Light ray 426 of a first wavelength range passes through the interior of the wavelength conversion element and exits through surface 406 without conversion. Usually, only a portion of the light of a first wavelength range entering the wavelength conversion element is converted into light of a second wavelength range.

Another embodiment of the present invention is light conversion device 430 illustrated in a side cross-sectional view in FIG. 4B. Light conversion device 430 includes a wavelength conversion element 432, a heat sink 412 in thermal contact with the wavelength conversion element and an optional reflector 414.

Light conversion device 430 differs from light conversion device 400 in that light conversion device 430 has a tapered wavelength conversion element 432. A tapered solid can help direct light of a second wavelength through one surface, the wide light output surface 436.

The wavelength conversion element 432 has at least one light input surface and at least one light output surface. For the example device 430, surface 434 is a light input surface and at least one surface 436 is a light output surface. Light output surface 436 has a larger area than the light input surface 434. Light of a first wavelength range enters the wavelength conversion element through the input surface 434. The wavelength conversion element converts at least a portion of the light of a first wavelength range into light of a second wavelength range. The second wavelength range is different than the first wavelength range. The light of a second wavelength range is emitted isotropically within the wavelength conversion element. Some of the light of a second wavelength range will exit the designated output surface 436. However, some of the light of a second wavelength range may also exit other surfaces including the input surface 434, surface 438, exposed portions of surface 440, the front surface (not shown) and the back surface (not shown).

The heat sink 412 removes heat generated within the wavelength conversion element 432 during wavelength conversion. The heat sink is in thermal contact with surface 440 of the wavelength conversion element.

Optional reflector 414 is interposed between surface 440 of the wavelength conversion element 432 and the heat sink 412. Reflector 414 is useful for light conversion device 430 if heat sink 412 has a low reflectivity to light. Preferably, the reflector reflects both light of a first wavelength and light of a second wavelength and prevents light from being absorbed by the heat sink.

Light rays 450, 452, 454, 456 and 458 illustrate the operation of light conversion device 430. Light ray 450 of a first wavelength range enters wavelength conversion element 432 through surface 434. Wavelength conversion element 432 converts light ray 450 of a first wavelength range into light ray 452 of a second wavelength range. The second wavelength range is different than the first wavelength range. Light ray 452 of a second wavelength range undergoes total internal reflection from surface 438 and exits wavelength conversion element 432 through surface 436. Angled surface 438 helps to redirect light via total internal reflection through the light output surface 436.

Light ray 454 of a first wavelength range enters wavelength conversion element 432 through surface 434. Wavelength conversion element 432 converts light ray 454 of a first wavelength range into light ray 456 of a second wavelength range. The second wavelength range is different than the first wavelength range. Light ray 456 of a second wavelength range is reflected by reflector 414 on surface 440 and exits wavelength conversion element 432 through surface 436.

Light ray 458 of a first wavelength range enters wavelength conversion element 432 through surface 434. Light ray 458 of a first wavelength range passes through the interior of the wavelength conversion element and exits through surface 436 without conversion. Usually, only a portion of the light of a first wavelength range entering the wavelength conversion element is converted into light of a second wavelength range.

Another embodiment of the present invention is light conversion device 460 illustrated in a side cross-sectional view in FIG. 4C and in a bottom plan view in FIG. 4D. Light conversion device 460 includes a wavelength conversion element 462, a heat sink 472 in thermal contact with the bottom surface 464 of the wavelength conversion element and an optional reflector 474.

The wavelength conversion element 462 is a three-dimensional solid fabricated from any wavelength conversion material that has a thermal conductivity greater than 1 W/m-K. In FIG. 4C, the wavelength conversion element 462 has a rectangular cross-section with four illustrated surfaces, 464, 466, 468 and 470, corresponding to four surfaces of a six-sided rectangular solid.

Suitable materials for wavelength conversion element 462 include monocrystalline solids, polycrystalline solids, substantially densified ceramic solids, amorphous solids and composite solids that have thermal conductivities greater than 1 W/m-K. Example materials are listed above.

The wavelength conversion element 462 has at least one light input surface and at least one light output surface. For the example device 460, surface 464 is a light input surface and at least surfaces 466, 468 and 470 are light output surfaces. In addition, the front and back surfaces (not shown) of the wavelength conversion element may also be light output surfaces. Light of a first wavelength range enters the wavelength conversion element through the light input surface 464. The wavelength conversion element converts at least a portion of the light of a first wavelength range into light of a second wavelength range. The second wavelength range is different than the first wavelength range. The light of a second wavelength range is emitted isotropically within the wavelength conversion element. Therefore, the light of a second wavelength range may exit more than one surface of the wavelength conversion element. Some of the light of a second wavelength range will exit the designated light output surfaces 466, 468 and 470. However, some of the light of a second wavelength range may also exit the front surface (not shown) and the back surface (not shown).

The heat sink 472 removes heat generated within the wavelength conversion element 462 during wavelength conversion. The shape of the heat sink in FIGS. 4C and 4D is a square with a hole in the center to allow light to enter input surface 464 of the wavelength conversion element. The heat sink is in thermal contact with surface 464 of the wavelength conversion element.

Optional reflector 474 is interposed between surface 464 of the wavelength conversion element 462 and the heat sink 472. Reflector 414 is useful for wavelength conversion device 460 if heat sink 472 has a low reflectivity to light. Preferably, the reflector reflects both light of a first wavelength and light of a second wavelength and prevents light from being absorbed by the heat sink.

Light rays 480, 481, 482, 483, 484 and 485 illustrate the operation of light conversion device 460. Light ray 480 of a first wavelength range enters wavelength conversion element 462 through surface 464. Wavelength conversion element 462 converts light ray 480 of a first wavelength range into light ray 481 of a second wavelength range. The second wavelength range is different than the first wavelength range. Light ray 481 of a second wavelength range exits wavelength conversion element 462 through surface 468.

Light ray 482 of a first wavelength range enters wavelength conversion element 462 through surface 464. Wavelength conversion element 462 converts light ray 482 of a first wavelength range into light ray 483 of a second wavelength range. The second wavelength range is different than the first wavelength range. Light ray 483 of a second wavelength range exits wavelength conversion element 462 through surface 466.

Light ray 484 of a first wavelength range enters wavelength conversion element 462 through surface 464. Wavelength conversion element 462 converts light ray 484 of a first wavelength range into light ray 485 of a second wavelength range. The second wavelength range is different than the first wavelength range. Light ray 485 of a second wavelength range exits wavelength conversion element 462 through surface 470.

The heat flow for the wavelength conversion devices 400, 430 and 460 is illustrated schematically in FIG. 4E. The wavelength conversion element has thermal resistance 490 (R_{WCE}) and the heat sink has thermal resistance 492 (R_{HW}). Heat flows in series from the wavelength conversion element and through the heat sink to the ambient environment 494. The heat sink provides a direct thermal pathway to ambient.

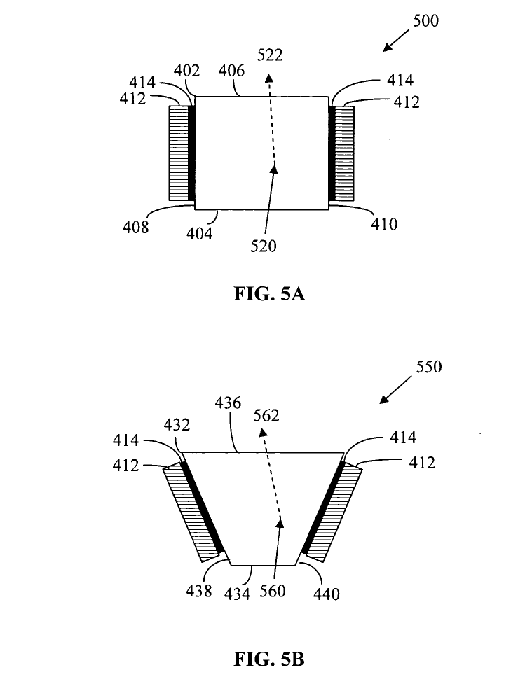

Other embodiments of this invention include more than one heat sink in thermal contact with the wavelength conversion element. Two example embodiments that have two heat sinks for each wavelength conversion element are illustrated in FIGS. 5A and 5B. Note that it is also within the scope of this invention that three or more heat sinks can be placed in thermal contact with a single wavelength conversion element.

Another embodiment of this invention is light conversion device 500, shown in a side cross-sectional view in FIG. 5A. Light conversion device 500 is similar to light conversion device 400 except that light conversion device 500 has two heat sinks 412 in thermal contact with the wavelength conversion element 402. Two optional reflectors 414 are interposed between the heat sinks and the wavelength conversion element. Having two heat sinks instead of one heat sink helps to increase the heat flow from the wavelength conversion element and reduce the temperature of the element during the process of wavelength conversion. The two reflectors are in contact with surfaces 408 and 410 and the two heat sinks are in thermal contact with surfaces 408 and 410 via the two reflectors. In this manner the maximum amount of light can be directed into the desired output distribution and output surface.

Light rays 520 and 522 illustrate the operation of light conversion device 500. Light ray 520 of a first wavelength range enters wavelength conversion element 402 through surface 404. Wavelength conversion element 402 converts light ray 520 of a first wavelength range into light ray 522 of a second wavelength range. The second wavelength range is different than the first wavelength range. Light ray 522 of a second wavelength range exits wavelength conversion element 402 through surface 406.

Another embodiment of this invention is light conversion device 550, shown in a side cross-sectional view in FIG. 5B. Light conversion device 550 is similar to light conversion device 430 except that light conversion device 550 has two heat sinks 412 in thermal contact with the wavelength conversion element 432. Two optional reflectors 414 are interposed between the heat sinks and the wavelength conversion element. Having two heat sinks instead of one heat sink helps to increase the heat flow from the wavelength conversion element and reduce the temperature of the element during the process of wavelength conversion. The two reflectors are in contact with surfaces 438 and 440 and the two heat sinks are in thermal contact with surfaces 438 and 440 via the two reflectors. The two reflectors direct the maximum amount of light into the desired output distribution and to the desired output surface 436. The directive reflectors 414, the input surface 434 and the output surface 436 may also include textured, micro-optical, and subwavelength elements, photonic crystal structures, multilayered filters and polarization dependent structures in order to enhance or modify the light output of light conversion device 550.

Light rays 560 and 562 illustrate the operation of light conversion device 550. Light ray 560 of a first wavelength range enters wavelength conversion element 432 through surface 434. Wavelength conversion element 432 converts light ray 560 of a first wavelength range into light ray 562 of a second wavelength range. The second wavelength range is different than the first wavelength range. Light ray 562 of a second wavelength range exits wavelength conversion element 432 through surface 436.

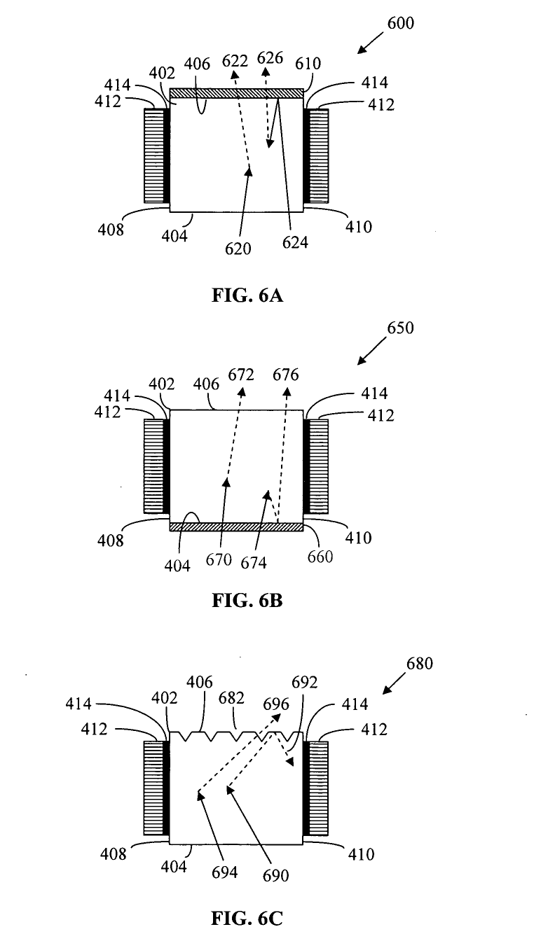

Other embodiments of this invention have modifications or additions to the input surface and/or the output surface of the wavelength conversion element. Three examples are illustrated in FIGS. 6A-6C.

Another embodiment of this invention is light conversion device 600, illustrated in a side cross-sectional view in FIG. 6A. Light conversion device 600 is similar to light conversion device 500 except that light conversion device 600 has a first dichroic mirror 610 fabricated on or positioned in close proximity to light output surface 406. The first dichroic mirror transmits light of a second wavelength range, such as light ray 622, and reflects light of a first wavelength range, such as light ray 624, back into the wavelength conversion element. The reflected light of a second wavelength range has another chance of being absorbed by the wavelength conversion element and converted to light of a second wavelength range.

For example, light ray 620 of a first wavelength range enters the wavelength conversion element through light input surface 404. The wavelength conversion element converts light ray 620 of a first wavelength range into light ray 622 of a second wavelength range. Light ray 622 exits the wavelength conversion element 402 through surface 406 and exits light conversion device 600 by passing through first dichroic mirror 610.

Light ray 624 of a first wavelength range enters the wavelength conversion element through light input surface 404. The light ray passes through the wavelength conversion element without conversion and is reflected back into the wavelength conversion element by the first dichroic mirror. The wavelength conversion element then converts light ray 624 of a first wavelength range in to light ray 626 of a second wavelength range. Light ray 626 exits the wavelength conversion element 402 through surface 406 and passes through the first dichroic mirror 610 to exit the light conversion device 600.

Another embodiment of this invention is light conversion device 650, illustrated in a side cross-sectional view in FIG. 6B. Light conversion device 650 is similar to light conversion device 500 except that light conversion device 650 has a second dichroic mirror 660 fabricated on or positioned in close proximity to light input surface 404. The second dichroic mirror transmits light of a first wavelength range, such as light rays 670 and 674, and reflects light of a second wavelength range, such as light ray 676, back into the wavelength conversion element. The reflected light of a second wavelength range is prevented from traveling back to the light-emitting device (not shown).

For example, light ray 670 of a first wavelength range enters the wavelength conversion element through the second dichroic mirror 660 and through light input surface 404. The wavelength conversion element converts light ray 670 of a first wavelength range into light ray 672 of a second wavelength range. Light ray 672 exits the wavelength conversion element through surface 406.

Light ray 674 of a first wavelength range enters the wavelength conversion element through the second dichroic mirror and through light input surface 404. The wavelength conversion element converts light ray 674 of a first wavelength range into light ray 676 of a second wavelength range. Light ray 676 can be emitted in any direction. In this example, light ray 676 is directed toward surface 404 and toward the second dichroic mirror. The second dichroic mirror reflects light ray 676 of a second wavelength range and redirects the ray to the output surface 406. Light ray 676 exits the wavelength conversion element 402 through surface 406.

Another embodiment of this invention is light conversion device 680, illustrated in a side cross-sectional view in FIG. 6C. Light conversion device 680 is similar to light conversion device 500 except that light conversion device 680 has light extraction elements 682 fabricated into or on the light output surface 406. The light extraction elements reduce the effects of total internal reflection for light of a second wavelength range that is emitted inside the wavelength conversion element and increase the amount of light of a second wavelength range that can exit the wavelength conversion element. The light extraction elements can include, but are not limited to, depressions in the shape of pyramids, hemispheres or grooves, elevated areas in the shape of pyramids, hemispheres or ridges, surface texturing, or subwavelength features such a photonic crystal structures.

Example light ray 690 of a first wavelength range enters the wavelength conversion element through light input surface 404. The wavelength conversion element converts light ray 690 of a first wavelength range into light ray 692 of a second wavelength range. Light ray 692 is directed to surface 406 at an angle greater than the critical angle for total internal reflection. Light ray 692 is reflected by surface 406 and remains inside the wavelength conversion element.

Example light ray 694 of a first wavelength range enters the wavelength conversion element through light input surface 404. The wavelength conversion element converts light ray 694 of a first wavelength range into light ray 696 of a second wavelength range. Light ray 696 is directed to a light extraction element 682 in the light output surface 406. Light ray 696 does not undergo total internal reflection and exits the wavelength conversion element 402 through the surface of the light extraction element.

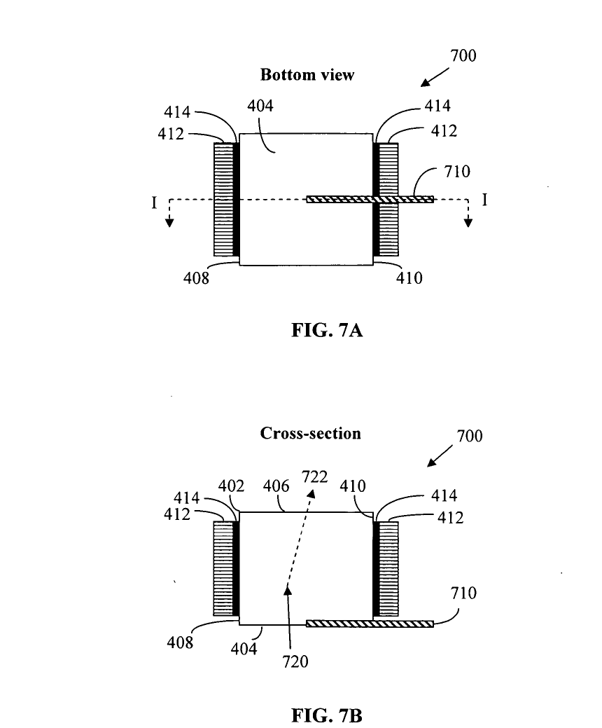

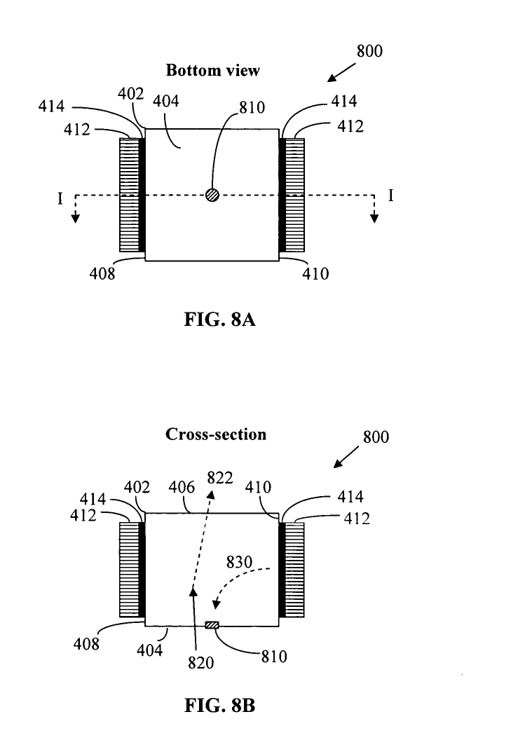

Other embodiments of this invention are light conversion devices that have an electrical interconnect means attached to the wavelength conversion element. Two examples of electrical interconnect means are illustrated in FIGS. 7 and 8.

Another embodiment of this invention is light conversion device 700, illustrated in a bottom plan view in FIG. 7A. FIG. 7B shows a side cross-sectional view along the I-I plane indicated in FIG. 7A. Light conversion device 700 is similar to light conversion device 500 except that light conversion device 700 includes an electrical interconnect means. The electrical interconnect means is an electrical connection 710 attached to or partially embedded into light input surface 404. The electrical connection allows light conversion device 700 to be positioned close by or bonded to a light-emitting device such as an LED (not shown) that has a top electrical contact. The electrical connection 710 can be bonded or soldered to a top contact of a light-emitting device that would otherwise be covered by the wavelength conversion device and be inaccessible to wire bonding or other standard interconnection techniques. The electrical connection covers only a small portion of surface 404 and allows light, such as example light ray 720, to easily enter the wavelength conversion element. The electrical connection can be, for example, a patterned metal such as aluminum, copper or gold, or the electrical connection can be a metal wire or metal structure embedded in a groove that is fabricated into the surface 404. The groove can be etched into the surface by any standard wet or dry etching process or can be fabricated by laser etching processes. A preferred etching process is laser ablation using a pulsed ultraviolet laser. For example, a suitable laser is a pulsed diode-pumped-solid-state (DPSS) laser that is frequency tripled or frequency quadrupled in order to emit ultraviolet light for laser ablation.

Another embodiment of this invention is light conversion device 800, illustrated in a bottom plan view in FIG. 8A. FIG. 8B shows a side cross-sectional view along the I-I plane indicated in FIG. 8A. Light conversion device 800 is similar to light conversion device 500 except that light conversion device 800 includes an electrical interconnect means. In this embodiment, the wavelength conversion element 402 must be electrically conducting. An example of an electrically conducting wavelength conversion element is doped zinc oxide.

The electrical interconnect means includes an electrically conducting heat sink 412, an optional electrically conducting reflector 414, an electrically conducting wavelength conversion element and an electrical contact 810 positioned on light input surface 404. Electrons or holes can flow from the heat sink, through the optional reflector, through the wavelength conversion element and to the electrical contact 810 via pathway 830. The electrical pathway and electrical contact 810 allow light conversion device 800 to be positioned close by or to be bonded to a light-emitting device such as an LED (not shown) that has a top electrical contact. The electrical contact 810 can be connected, bonded or soldered to a top contact of the light-emitting device that would otherwise be covered by the wavelength conversion device and be inaccessible to wire bonding or other standard interconnection techniques. The electrical contact 810 can be, for example, a patterned metal such as aluminum, copper or gold, an electrically conducting epoxy or a metal structure embedded in a hole that is fabricated into the surface 404. The hole can be etched into the surface by any standard wet or dry etching process or can be fabricated by laser etching processes. A preferred etching process is laser ablation using a pulsed ultraviolet laser.

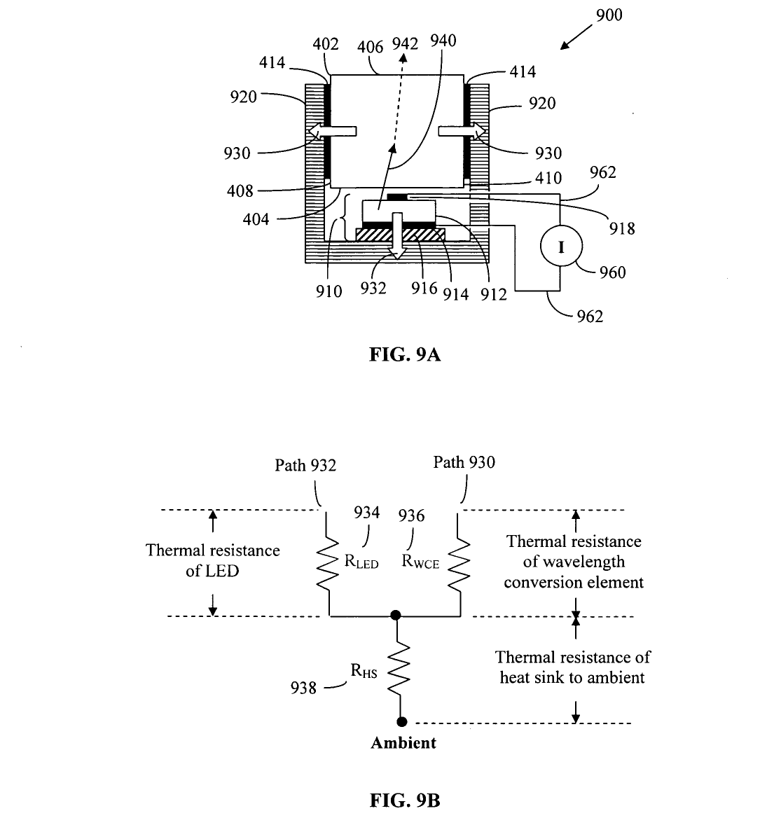

The wavelength conversion elements and light conversion devices described above can be combined with solid-state, light-emitting devices to form wavelength-converting solid-state light sources. Preferred solid-state, light-emitting devices for this invention emit internally generated light of a first wavelength range and include one or more LEDs and/or diode lasers. LEDs include surface-emitting, side-emitting, edge-emitting and super-luminescent edge-emitting LEDs. Preferred light-emitting devices for this invention are surface-emitting LEDs that emit blue or ultraviolet light. Preferred LEDs include devices that have two top electrical contacts, two bottom electrical contacts or one top and one bottom electrical contact. For simplicity, the LEDs in FIGS. 9-12 are illustrated to have one top contact and one bottom contact. However, it is within the scope of this invention that the light-emitting devices may have other electrical contact arrangements.

Preferably the LEDs of this invention reflect externally incident light with a reflectivity greater than 40%. One example of externally incident light is internally generated light of a first wavelength range that is emitted by an LED and then is reflected and recycled back to the same LED or to a different LED. In addition, externally incident light can be light of a second wavelength range that is emitted by the wavelength conversion element and directed to an LED. The externally incident light directed to an LED is reflected by the top electrode of the LED or passes through the multilayer semiconductor structure and is reflected by the bottom electrode of the LED or is absorbed by the LED. It is preferred that absorption of light by the LED be minimized and that reflection of light be maximized. More preferably, the LEDs of this invention have a reflectivity greater than 50% for externally incident light. Most preferably, the LEDs of this invention have a reflectivity greater than 60% for externally incident light. Since some of the light emitted by the LEDs and wavelength conversion elements will be directed back to the LEDs, utilizing LEDs with high reflectivity for externally incident light will improve the output efficiency of the light sources.

Light sources of this invention can emit high-intensity beams of light. For example, light sources of this invention can emit greater than 0.25 optical watts per square millimeter of output surface area. A light intensity of 0.25 optical watts per square millimeter of output surface area is equivalent to 25 optical watts per square centimeter. The light emitted from the light source can be a mixture of light of a first wavelength range and light of a second wavelength range.

Preferably the LEDs utilized in the light sources of this invention emit greater than 0.25 optical watts of light per square millimeter of LED output surface area. More preferably, the LEDs of this invention emit greater than 0.5 optical watts per square millimeter of output surface area. Inside the wavelength conversion elements of this invention, the light flux density can be greater then 0.5 optical watts per cubic millimeter.

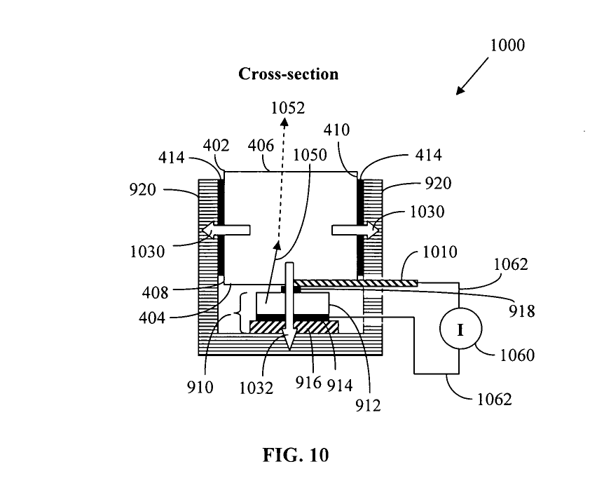

FIGS. 9-10 illustrate light sources that utilize one heat sink for both the LED and the wavelength conversion element. In FIG. 9, the wavelength conversion element and the LED are not in direct physical and thermal contact, reducing the possibility that the wavelength conversion element will overheat the LED or the LED will overheat the wavelength conversion element. If the wavelength conversion element is overheated, thermal quenching may occur and the light output from the wavelength conversion element will be reduced. If the LED is overheated, the LED will become less efficient and the light output from the LED will drop. In FIG. 10, the wavelength conversion element and the LED are in physical and thermal contact and the wavelength conversion element includes an optional electrical interconnect means.

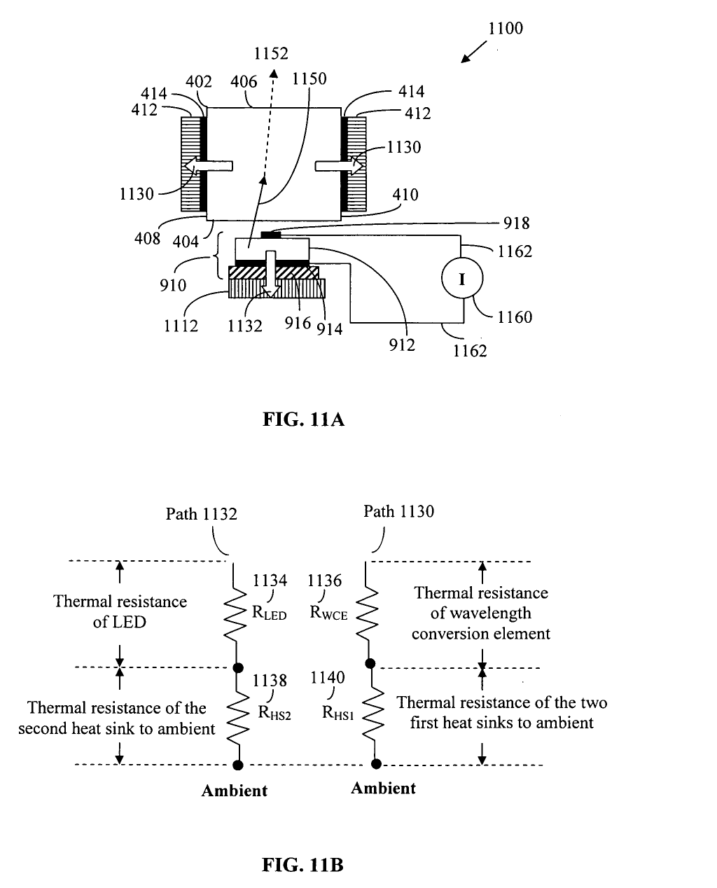

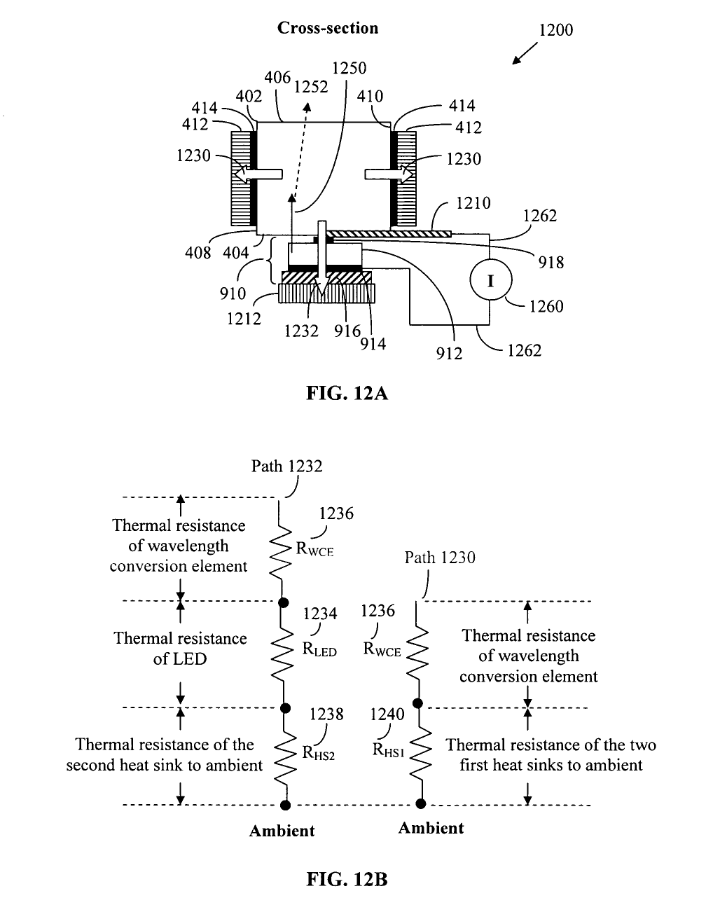

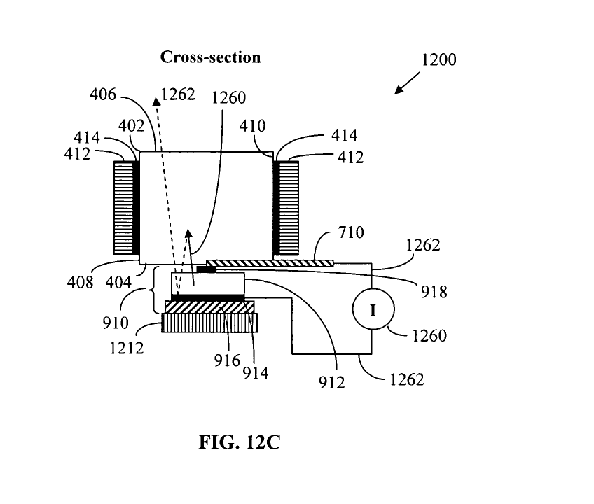

FIGS. 11-12 illustrate light sources that utilize two or more heat sinks such that the LED and the wavelength conversion element have separate heat sinks. In FIG. 11, the wavelength conversion element and the LED are not in direct physical and thermal contact, reducing the possibility that the wavelength conversion element will overheat the LED or the LED will overheat the wavelength conversion element. In FIG. 12, the wavelength conversion element and the LED are in physical and thermal contact and the wavelength conversion element includes an optional electrical interconnect means. For FIG. 12, heat flow from the wavelength conversion element has at least two separate pathways, one pathway through the LED and at least a second additional pathway directly to one or more heat sinks.

An embodiment of this invention is light source 900 illustrated in a side cross-sectional view in FIG. 9A. Light source 900 includes a wavelength conversion element 402, an LED 910 that emits internally generated light of a first wavelength range, a heat sink 920 and optional reflectors 414 interposed between the wavelength conversion element and the heat sinks.

Wavelength conversion element 402 converts light of a first wavelength range into light of second wavelength range and has been described above. The wavelength conversion element has at least one light input surface, illustrated as surface 404 in FIG. 9A, at least one light output surface 406 and has a thermal conductivity greater than 1 W/m-K. More preferred wavelength conversion elements have a thermal conductivity greater than 10 W/m-K. Most preferred wavelength conversion elements have a thermal conductivity greater than 50 W/m-K. Exemplary wavelength conversion elements are fabricated from monocrystalline solids, polycrystalline solids, substantially densified ceramic solids, amorphous solids or composite solids. Examples of suitable solids were listed above. The wavelength conversion element is in thermal contact with heat sink 920 via the optional reflectors 414, but is not in direct physical or thermal contact with LED 910.

For simplicity, light source 900 is illustrated with one LED. However, light source 900 may include more than one LED. LED 910 includes a multilayer semiconductor structure 912, a top contact 918, a bottom contact 914 and a sub-mount 916. The multilayer semiconductor structure can be fabricated from any light-emitting semiconductor material. Exemplary semiconductor materials emit blue or ultraviolet light and include gallium-nitride-based materials such as gallium nitride (GaN), aluminum nitride (AlN), indium nitride (InN), indium gallium nitride (InGaN), aluminum gallium nitride (AlGaN) and aluminum indium gallium nitride (AlInGaN). Other exemplary materials include, but are not limited to, zinc oxide (ZnO) based semiconductor materials. When a current is supplied through the top and bottom contacts of the LED, the multilayer semiconductor structure emits light of a first wavelength range.

The heat sink is a single heat sink that is in thermal contact with both the LED and the wavelength conversion element. In FIG. 9A, the heat sink is in thermal contact with two surfaces, surface 408 and surface 410, of the wavelength conversion element. However, it is within the scope of this invention that the heat sink can be in thermal contact with one surface only, two surfaces only, three surfaces only or more than three surfaces of the wavelength conversion element. The heat sink transports heat to the ambient environment. The heat may be dissipated directly to the ambient environment by convective airflow or forced airflow. Alternatively, the heat from the heat sink may be dissipated to the ambient environment by additional elements or assemblies (not shown) such as air fins, heat spreaders, heat pipes or liquid cooling assemblies.

The optional reflectors 414 reflect light of a first wavelength range and light of a second wavelength range. The reflectors prevent light of either first or second wavelength range from reaching the heat sink and being absorbed by the heat sink.

Heat is removed from the wavelength conversion element via pathway 930, which is illustrated by the two arrows in FIG. 9A and illustrated schematically in FIG. 9B. Heat is removed from the LED via pathway 932. In both cases, heat flows through the single heat sink 920 to the ambient environment. However, the LED and the wavelength conversion element do not have a direct thermal connection.

When a current source 960 supplies current via wires 962 to the top and bottom contacts of the LED, the multilayer semiconductor structure emits light of a first wavelength range. Light rays 940 and 942 illustrate the operation of light source 900. Example light ray 940 of a first wavelength range is emitted by the multilayer semiconductor structure of LED 910 and is directed toward the wavelength conversion element. Light ray 940 enters the wavelength conversion element through surface 404 and is converted to light ray 942 of a second wavelength range. Light ray 942 of a second wavelength range passes through surface 406 and exits light source 900.

The wavelength conversion element of light source 900 may also include other elements that are not illustrated in FIG. 9A. For example, the wavelength conversion element may include a dichroic mirror on light input surface 404, a dichroic mirror on light output surface 406 and/or light extraction elements on light output surface 406. The extra elements have been described above. In FIG. 9B, R_{LED} is the thermal resistance 934 of LED 910, R_{WCE} is the thermal resistance 936 of wavelength conversion element 402 and R_{HS} is the thermal resistance 938 of the heat sink 920. As illustrated in FIGS. 9A and 9B, the heat emitted by both the LED and the wavelength conversion element passes through the one heat sink 920 to ambient.

FIG. 10 illustrates another embodiment of this invention. FIG. 10 is a side cross-sectional view of light source 1000. Light source 1000 is similar to light source 900 except that the wavelength conversion element for light source 1000 is in direct thermal contact with LED 910. In addition, the wavelength conversion element includes an embedded electrical connector 1010 that facilitates the electrical connection to top electrode 918 of the LED. Top electrode 918 is covered by the wavelength conversion element and is not readily accessible by conventional wire bonding or other interconnection methods.

Overall, light source 1000 includes a wavelength conversion element 402 having an embedded electrical connector 1010, an LED 910 that emits internally generated light of a first wavelength range, a heat sink 920 and optional reflectors 414 interposed between the wavelength conversion element and the heat sinks. Wavelength conversion element 402 converts light of a first wavelength range into light of second wavelength range. The wavelength conversion element is in thermal contact with heat sink 920 via the optional reflectors 414 and is also in thermal contact with LED 910. Electrical connector 1010 provides the thermal connection of the wavelength conversion element to the LED, illustrated as pathway 1032. Optionally, the wavelength conversion element can also be bonded (not shown) to the top surface of the LED. Suitable bonding materials include low melting point, optically transparent glasses. Bonding the wavelength conversion element to the LED may improve the light extraction efficiency of the LED.

Heat is removed from the wavelength conversion element via pathway 1030, which is illustrated by the two arrows in FIG. 10, and via pathway 1032 through the LED. Heat is removed from the LED also via pathway 1032. In both cases, heat flows through the single heat sink 920 to the ambient environment.

When a current source 1060 supplies current via wires 1062 to the top and bottom contacts of the LED, the multilayer semiconductor structure emits light of a first wavelength range. Light rays 1050 and 1052 illustrate the operation of light source 1000. Example light ray 1050 of a first wavelength range is emitted by the multilayer semiconductor structure of LED 910 and is directed toward the wavelength conversion element. Light ray 1050 enters the wavelength conversion element through surface 404 and is converted to light ray 1052 of a second wavelength range. Light ray 1052 of a second wavelength range passes through surface 406 and exits light source 1000.

Another embodiment of this invention is a light source that includes a wavelength conversion element that has an input surface and an output surface, a light emitting diode positioned adjacent to the input surface, at least one first heat sink in thermal contact with the wavelength conversion element and a second heat sink in thermal contact with the light emitting diode. The first heat sink is not in direct thermal contact with the second heat sink. The wavelength conversion element and the light emitting diode can be in direct thermal contact or physically separated. Having at least two heat sinks, at least one for the wavelength conversion element and one for the LED, helps to cool the wavelength conversion element and prevent the wavelength conversion element from overheating the LED or the LED from overheating the wavelength conversion element. In this manner, the wavelength conversion element and the LED can be thermally isolated. This enables the optional use of active thermal cooling means on either the wavelength conversion element or the LED or both. This is desirable because the operating point for the wavelength conversion element and the LED are not necessarily the same. For example, one might decide to use a thermal electric cooler as known in the art to maintain the junction temperature of the LED below ambient. This substantially increases the thermal load to the LED heat sink. It is preferred that the wavelength conversion material not be cooled via the LED heat sink in this case. Alternately, liquid cooling means might be used to cool the wavelength conversion material, while the LED is cooled via forced air convection cooling.

FIG. 11A is a side cross-sectional view of exemplary light source 1100. Light source 1100 incorporates the light conversion device 500 described above. Light source 1100 includes a wavelength conversion element 402, two first heat sinks 412 in thermal contact with surfaces 408 and 410 of the wavelength conversion element, an LED 910 and a second heat sink 1112 in thermal contact with the LED. In this example, the wavelength conversion element has two heat sinks. Alternatively, the wavelength conversion element could have only one heat sink or more than two heat sinks in thermal contact with the element. LED 910 emits internally generated light of a first wavelength range. Optional reflectors 414 interposed between the wavelength conversion element and the first heat sinks 412 reflect light of a first wavelength range and light of a second wavelength range. In FIG. 11A, the wavelength conversion element and the LED are not in physical or thermal contact.

Heat is removed from the wavelength conversion element via two pathways 1130 to the two first heat sinks 412 located on sides 408 and 410 of the wavelength conversion element. Pathway 1130 is also shown schematically in FIG. 11B. Heat is removed from the LED via pathway 1132 to the second heat sink 1112. Pathway 1132 is also illustrated in FIG. 11B. In this embodiment, there are separate heat sinks and separate heat removal paths for the wavelength conversion element and for the LED.

The wavelength conversion element of light source 1100 may also include other elements that are not illustrated in FIG. 11A. For example, the wavelength conversion element may include a dichroic mirror on light input surface 404, a dichroic mirror on light output surface 406 and/or light extraction elements on light output surface 406. The extra elements have been described above.

When a current source 1160 supplies current via wires 1162 to the top and bottom contacts of the LED, the multilayer semiconductor structure emits light of a first wavelength range. Light rays 1150 and 1152 illustrate the operation of light source 1100. Example light ray 1150 of a first wavelength range is emitted by the multilayer semiconductor structure of LED 910 and is directed toward the wavelength conversion element. Light ray 1150 of a first wavelength range enters the wavelength conversion element through surface 404 and is converted to light ray 1152 of a second wavelength range. Light ray 1152 of a second wavelength range passes through surface 406 and exits light source 1100. In FIG. 11B, R_{LED} is the thermal resistance 1134 of LED 910, R_{WCE} is the thermal resistance 1136 of the wavelength conversion element 402, R_{HS1} is the thermal resistance 1140 of the two first heat sinks 412 to ambient and R_{HS2} is the thermal resistance 1138 of the second heat sink 1112 to ambient.

Another embodiment of this invention is light source 1200, illustrated in a side cross-sectional view in FIGS. 12A and 12C. Light source 1200 is similar to light source 1100. However, the wavelength conversion element in light source 1200 is in direct physical and thermal contact with the LED. In addition, the wavelength conversion element includes an embedded electrical connector 1210 that facilitates the electrical connection to top electrode 918 of the LED. Top electrode 918 is covered by the wavelength conversion element and is not readily accessible by conventional wire bonding or other interconnection methods.

Overall, light source 1200 includes a wavelength conversion element 402 having an embedded electrical connector 1210, two first heat sinks 412 in thermal contact with the wavelength conversion element, an LED 910 that emits internally generated light of a first wavelength range, a second heat sink 1212 in thermal contact with the LED and optional reflectors 414 interposed between the wavelength conversion element and the first heat sinks. Wavelength conversion element 402 converts light of a first wavelength range into light of second wavelength range. The wavelength conversion element is in thermal contact with first heat sinks 412 via the optional reflectors 414 and is also in thermal contact with LED 910. Electrical connector 1210 provides the thermal connection of the wavelength conversion element to the LED, illustrated as pathway 1232. Optionally, the wavelength conversion element can also be bonded (not shown) to the top surface of the LED. Suitable bonding materials include low melting point, optically transparent glasses. Bonding the wavelength conversion element to the LED may improve the light extraction efficiency of the LED.

Heat is removed from the wavelength conversion element via two pathways 1230, which are illustrated by the two arrows in FIG. 12A, and via pathway 1232 through the LED. Heat is removed from the LED also via pathway 1232. Heat flows through the three heat sinks to the ambient environment. Pathways 1230 and 1232 are also illustrated schematically in FIG. 12B. In FIG. 12B, R_{LED} is the thermal resistance 1234 of LED 910, R_{WCE} is the thermal resistance 1236 of the wavelength conversion element 402, R_{HS2} is the thermal resistance 1238 of second heat sink 1212 to ambient and R_{HS1} is the thermal resistance 1240 of the first heat sinks 412 to ambient.

When a current source 1260 supplies current via wires 1262 to the top and bottom contacts of the LED, the multilayer semiconductor structure emits light of a first wavelength range. Light rays 1250 and 1252 in FIG. 12A illustrate the operation of light source 1200. Example light ray 1250 of a first wavelength range is emitted by the multilayer semiconductor structure of LED 910 and is directed toward the wavelength conversion element. Light ray 1250 of a first wavelength range enters the wavelength conversion element through surface 404 and is converted to light ray 1252 of a second wavelength range. Light ray 1252 of a second wavelength range passes through surface 406 and exits light source 1200.

The concept of light recycling and the desirability of utilizing LEDs that reflect externally incident light are illustrated in FIG. 12C. Light ray 1260 of a first wavelength range is emitted by the multilayer semiconductor structure 912 of LED 910 and directed to the wavelength conversion element. Light ray 1260 of a first wavelength range passed through surface 404 of the wavelength conversion element and is converted to light ray 1262 of a second wavelength range. Light ray 1262 can be emitted in any direction. In this example, light ray 1262 is directed through surface 404 a first time and is recycled back to LED 910. Light ray 1262 passes through the multilayer semiconductor structure a first time and is reflected by the bottom contact 914. The reflected light ray passes through the multilayer semiconductor structure a second time is directed back to the wavelength conversion element. Light ray 1262 of a second wavelength range passes through surface 404 a second time, passes through the interior of the wavelength conversion element without conversion and passes through surface 406 to exit light source 1200. The reflection of light ray 1262 by LED 910 increases the effective brightness of LED 910 and increases the output efficiency and brightness of light source 1200.

While the invention has been described in conjunction with specific embodiments and examples, it is evident to those skilled in the art that many alternatives, modifications and variations will be apparent in light of the foregoing description. Accordingly, the invention is intended to embrace all such alternatives, modifications and variations as fall within the spirit and scope of the appended claims.

What is claimed is:

1. A light conversion device, comprising:
a wavelength conversion element having a light input surface and a light output surface; and
a heat sink in thermal contact with said wavelength conversion element, said heat sink removing heat generated by said wavelength conversion element;
wherein said wavelength conversion element converts light of a first wavelength range into light of a second wavelength range, said second wavelength range being different from said first wavelength range, and wherein said wavelength conversion element is a thermally conducting solid having a thermal conductivity greater than 1 watt per meter per degree Kelvin.

2. A light conversion device as in claim 1, wherein said thermally conducting solid is a monocrystalline solid, a polycrystalline solid, a substantially densified ceramic solid, an amorphous solid or a composite solid.

3. A light conversion device as in claim 2, further comprising a reflector interposed between said wavelength conversion element and said heat sink, wherein said reflector reflects said light of a first wavelength range and reflects said light of a second wavelength range.

4. A light conversion device as in claim 3, further comprising an electrical interconnection means in said wavelength conversion element.

5. A light conversion device as in claim 4, wherein said electrical interconnection means is an electrical connector fabricated on or embedded in a portion of said light input surface.

6. A light conversion device as in claim 4, wherein said wavelength conversion element is electrically conducting, wherein said electrical interconnection means has an electrically conducting heat sink and an electrical contact positioned on said light input surface, and wherein the electrical current path extends from said heat sink through said electrically conducting wavelength conversion element to said electrical contact.

7. A light conversion device as in claim 3, further comprising a first dichroic mirror formed on said light output surface, wherein said first dichroic mirror transmits said light of said second wavelength range and reflects said light of said first wavelength range back into said wavelength conversion element.

8. A light conversion device as in claim 3, further comprising a second dichroic mirror formed on said light input surface, wherein said second dichroic mirror transmits said light of said first wavelength range and reflects said light of said second wavelength range back into said wavelength conversion element.

9. A light conversion device as in claim 3, further comprising light extraction elements fabricated on said light output surface.

10. A light conversion device as in claim 1, wherein said wavelength conversion element has a thermal conductivity greater than ten watts per meter per degree Kelvin.

11. A light conversion device as in claim 1, wherein said wavelength conversion element has a thermal conductivity greater than fifty watts per meter per degree Kelvin.

12. A light source, comprising:
a wavelength conversion element having a light input surface and a light output surface;
a light emitting diode adjacent to said light input surface, wherein said light emitting diode emits internally generated light in a first wavelength range, said light in said first wavelength range being directed through said light input surface; and
a heat sink in thermal contact with said light emitting diode and in thermal contact with said wavelength conversion element, said heat sink removing heat generated by said light emitting diode and heat generated by said wavelength conversion element;
wherein said wavelength conversion element converts said light of said first wavelength range into light of a second wavelength range, said second wavelength range being different from said first wavelength range and wherein said wavelength conversion element is a thermally conducting solid having a thermal conductivity greater than 1 watt per meter per degree Kelvin.

13. A light source as in claim 12, wherein said thermally conducting solid is a monocrystalline solid, a polycrystalline solid, a substantially densified ceramic solid, an amorphous solid or a composite solid.

14. A light source as in claim 12, wherein said wavelength conversion element has a thermal conductivity greater than ten watts per meter per degree Kelvin.

15. A light source as in claim 12, wherein said wavelength conversion element has a thermal conductivity greater than fifty watts per meter per degree Kelvin.

16. A light source, comprising:
a wavelength conversion element having a light input surface and a light output surface;
a first heat sink in thermal contact with said wavelength conversion element, said heat sink removing heat generated by said wavelength conversion element;
a light emitting diode adjacent to said light input surface, wherein said light emitting diode emits internally generated light in a first wavelength range, said light in said first wavelength range directed through said light input surface; and
a second heat sink in thermal contact with said light emitting diode, said second heat sink removing heat generated by said at least one light emitting diode;
wherein said wavelength conversion element converts said light of said first wavelength range into light of a second wavelength range, said second wavelength range being different from said first wavelength range and wherein said wavelength conversion element is a thermally conducting solid having a thermal conductivity greater than 1 watt per meter per degree Kelvin.

17. A light source as in claim 16, wherein said thermally conducting solid is a monocrystalline solid, a polycrystalline solid, a substantially densified ceramic solid, an amorphous solid or a composite solid.

18. A light source as in claim 17, wherein said wavelength conversion element has a thermal conductivity greater than ten watts per meter per degree Kelvin.

19. A light source as in claim 17, wherein said wavelength conversion element has a thermal conductivity greater than fifty watts per meter per degree Kelvin.

20. A light source as in claim 17, further comprising a reflector interposed between said wavelength conversion element and said first heat sink, wherein said reflector reflects said light of said first wavelength range and reflects said light of said second wavelength range.

21. A light source as in claim 17, further comprising an electrical interconnection means in said wavelength conversion element.

22. A light source as in claim 21, wherein said electrical interconnection means is an electrical connector fabricated on or embedded in a portion of said light input surface

23. A light source as in claim 21, wherein said wavelength conversion element and said first heat sink are electrically conducting, wherein said electrical interconnection means has an electrical contact positioned on said light input surface and wherein the electrical current path extends from said first heat sink, through said electrically conducting wavelength conversion element through said electrical contact.

24. A light source as in claim 17, wherein said light emitting diode reflects externally incident light with a reflectivity greater than 40 percent, wherein a portion of said light of a second wavelength range emitted by said wavelength conversion element is directed to said light emitting diode as externally incident light and wherein said externally incident light is reflected by said light emitting diode and directed through said wavelength conversion element and through said output surface, thereby increasing the light output of said light source.

25. A light source as in claim 17, wherein said light emitting diode emits greater than 0.25 optical watt per square millimeter of said internally generated light.

26. A light source as in claim 25, wherein said light emitting diode emits greater than 0.50 optical watt per square millimeter of said internally generated light.

27. A light source as in claim 17, wherein the light flux density of said light of a first wavelength range inside said wavelength conversion element is greater than 0.5 optical watt per cubic millimeter.

28. A light source as in claim 17, wherein the light output intensity of said light of a first wavelength range and said light of a second wavelength range is greater than 0.25 optical watt per square millimeter.
